(19) United States
(12) Patent Application Publication
(10) Pub. No.: US 2023/0299050 A1
(43) Pub. Date: Sep. 21, 2023

(54) TEST ARCHITECTURE FOR 3D STACKED CIRCUITS

(71) Applicant: QUALCOMM Incorporated, San Diego, CA (US)

(72) Inventors: Kunal Jain MANGILAL, San Diego, CA (US); Madan KRISHNAPPA, San Diego, CA (US)

(21) Appl. No.: 17/700,329

(22) Filed: Mar. 21, 2022

(51) Int. Cl. H01L 25/065; H01L 21/66; H01L 25/00

(52) U.S. Cl. CPC H01L 25/0657; H01L 22/34; H01L 22/12; H01L 25/50; H01L 2225/06513; H01L 2225/06541; H01L 2225/06596

(57) ABSTRACT

Stacked circuits are configured to facilitate post-stacking testing. According to one example, a stacked circuit may include a first die electrically coupled to a second die through a plurality of interconnects. The first die may include a test input interface configured to receive test data signals and a source test clock signal, a test output interface configured to convey test responses, a first test signal path, at least one first die-to-die output interface configured to convey to the second die the test data signals and a low-latency clock signal received from a low-latency clock path between the test input interface and the at least one first die-to-die output interface, and at least one first die-to-die input interface configured to receive test responses and the clock signal from the second die. Other aspects, embodiments, and features are also included.

### TECHNICAL FIELD

Various features relate to integrated circuit (IC) design and testing, and in particular to test architectures for three-dimensional (3D) stacked ICs.

### INTRODUCTION

Computational needs in integrated circuits are constantly increasing, especially with the growth in artificial intelligence (AI) and machine learning (ML) applications. Three-dimensional (3D) system integration has emerged as a key enabling technology to continue the scaling trajectory that Moore's Law predicted for future integrated circuit (IC) generations. More particularly, with 3D integration technology, components in a stacked IC can be placed on different dies, which can substantially reduce both the average and maximum distance between the components in the stacked IC and translate into significant savings in delay, power, and area footprint. Furthermore, 3D integration technology can enable the integration of heterogeneous devices, thereby making the entire system more compact and more efficient. Nevertheless, the success of 3D stacked ICs is predicated on the final post-bond yield.

Historically, focus on pre-bond testing was expected to improve the overall yield of 3D ICs, which involves testing each individual die in a 3D stacked IC prior to the bonding process, because manufacturers can avoid stacking defective dies with good dies. However, post-stacking testing discovered that defects still occur due to assembly, stacking of dies, and packaging. There is accordingly an ongoing need to provide efficient post-stacking testing features for 3D stacked circuits.

### BRIEF SUMMARY OF SOME EXAMPLES

The following presents a summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a form as a prelude to the more detailed description that is presented later.

Various features relate to stacked circuits (e.g., 3D stacked ICs) that facilitate post-stacking testing. One example provides a stacked circuit that includes a first die electrically coupled to a second die through a plurality of interconnects. The first die may include a test input interface configured to receive test data signals and a source test clock signal, a test output interface configured to convey test responses, a first test signal path configured to transition the test data signals from the source test clock to a first balanced clock tree, to test the first die using the test data signals transitioned to the first balanced clock tree, to transition the test data signals and resulting test responses from the first balanced clock tree to a low-latency clock, and to convey resulting test responses to the test output interface, at least one first die-to-die output interface configured to convey to the second die the test data signals and a low-latency clock signal received from a low-latency clock path between the test input interface and the at least one first die-to-die output interface, and at least one first die-to-die input interface configured to receive test responses and the clock signal from the second die.

Another example provides an apparatus that includes a first die electrically coupled to a second die in a 3D stacked circuit configuration. The first die may be configured to convey test data signals and a clock signal to the second die, where the first die includes a first tunable die-to-die output interface configured to tune at least one of the test data signals or the clock signal prior to being conveyed to the second die, and a first tunable die-to-die input interface configured to tune at least one of test response signals or the clock signal received from the second die. The second die may include a second tunable die-to-die input interface configured to tune the at least one of the test data signals or the clock signal received from the first die, and a second tunable die-to-die output interface configured to tune the at least one of the test response signals or the clock signal prior to being conveyed to the first die.

Another example provides a method for fabricating a stacked circuit. The method provides a first die and a second die, and electrically coupling the first die and the second die together to form a 3D stacked circuit. The first die may include a test input interface configured to receive test data signals and a source test clock signal, a test output interface configured to convey test responses, a first test signal path configured to transition the test data signals from the source test clock to a first balanced clock tree, to test the first die using the test data signals transitioned to the first balanced clock tree, to transition the test data signals and resulting test responses from the first balanced clock tree to a low-latency clock, and to convey resulting test responses to the test output interface, at least one first die-to-die output interface configured to convey to the second die the test data signals and a low-latency clock signal received from a low-latency clock path between the test input interface and the at least one first die-to-die output interface, and at least one first die-to-die input interface configured to receive test responses and the clock signal from the second die.

Yet another example provides a method operational on a stacked circuit. The method includes receiving test data signals and a source test clock in a first die, transitioning the test data signals from the source test clock to a first balanced clock tree, employing the test data signals transitioned to the first balanced clock tree to test the first die, where the test of the first die results in first die test responses, transitioning the test data signals to a low-latency clock, conveying the low-latency clock and the test data signals transitioned to the low-latency clock to a second die stacked on the first die and electrically coupled to the first die, transitioning the test data signals in the second die from the test clock to a second balanced clock tree, employing the test data signals transitioned to the second balanced clock tree to test the second die, wherein the test of the second die results in second die test responses, transitioning the second die test responses to the low-latency clock, and conveying the second die test responses and low-latency clock from the second die to the first die.

These and other aspects of the disclosure will become more fully understood upon a review of the detailed description, which follows. Other aspects, features, and examples of the present invention will become apparent to those of ordinary skill in the art, upon reviewing the following description of specific, exemplary examples in conjunction with the accompanying figures. While features may be discussed relative to certain examples and figures below, all examples can include one or more of the advantageous features discussed herein. In other words, while one or more examples may be discussed as having certain advantageous features, one or more of such features may also be used in accordance with the various examples of the invention discussed herein. In similar fashion, while exemplary examples may be discussed below as device, system, or method examples it should be understood that such exemplary examples can be implemented in various devices, systems, and methods.

### BRIEF DESCRIPTION OF THE DRAWINGS

FIG. 1 is a schematic diagram illustrating a stacked circuit 100 according to at least one embodiment.

FIG. 2 is a schematic diagram of a first die depicting select components according to at least one aspect.

FIG. 3 is a schematic diagram illustrating an output tunable delay circuit according to at least one aspect.

FIG. 4 is a schematic diagram illustrating an input tunable delay circuit according to at least one aspect.

FIG. 5 is a schematic diagram of a second die depicting select components according to at least one aspect.

FIG. 6 is a schematic diagram illustrating an example bus interface architecture between a first die and a second die according to at least one aspect.

FIG. 7 is a schematic diagram illustrating an example of an architecture for facilitating interface debugging and diagnoses according to at least one aspect.

FIG. 8 is a flow diagram illustrating at least one example of a method operational on a stacked circuit including at least a first die and at least a second die.

FIG. 9 is a flow diagram illustrating at least one example of a method of making a stacked circuit described herein.

FIG. 10 illustrates various electronic devices that may integrate a die, an electronic circuit, an integrated device, an integrated passive device (IPD), a passive component, a package, and/or a device package described herein.

FIG. 11 is a schematic diagram illustrating an example of a repairable interconnect between the first die and the second die according to at least one aspect.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The illustrations presented herein are, in some instances, not actual views of any particular stacked IC, but are merely idealized representations which are employed to describe the present disclosure. Additionally, elements common between figures may retain the same numerical designation.

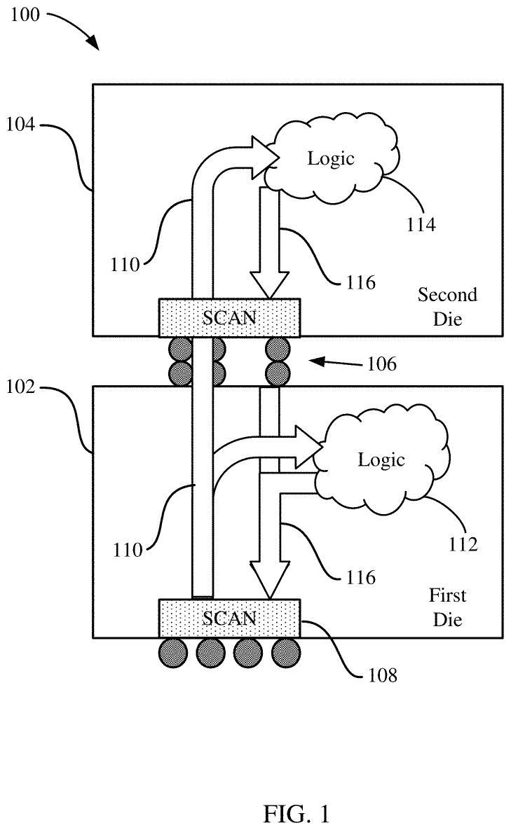

The present disclosure describes 3D stacked ICs utilizing a common scan interface in the first die to scan both the first die and one or more dies stacked on the first die. FIG. 1 is a schematic diagram illustrating a stacked circuit 100 according to at least one example of the present disclosure. As shown, the stacked circuit 100 may be implemented as a 3D stacked IC with a first die 102 positioned at the bottom and a second die 104 electrically coupled to the first die through a plurality of interconnects 106. The plurality of interconnects 106 may provide at least one electrical path (e.g., electrical connection) between the first die 102 and the second die 104. The plurality of interconnects 106 shown in FIG. 1 may conceptually represent several interconnects, including traces, vias, solder interconnects, and/or pads.

The stacked circuit 100 in FIG. 1 generally employs the Flexible Parallel Port (FPP) implementation, as defined by IEEE 1838 (2019), whereby a single scan interface 108 is employed to facilitate testing of all the stacked dies. More specifically, a scan interface 108 can receive test data signals 110 for testing the first die 102 at the first die testing logic 112 and for testing the second die 104 at the second die testing logic 114. Similarly, resulting test responses 116 are conveyed from both the first die 102 and the second die 104 out of the scan interface 108.

Although only two dies 102, 104 are shown in FIG. 1 and throughout the examples depicted in this disclosure, it should be apparent that features and aspects of the present disclosure can be implemented in stacked circuits employing two does, or more than two dies stacked together to form a 3D stacked IC.

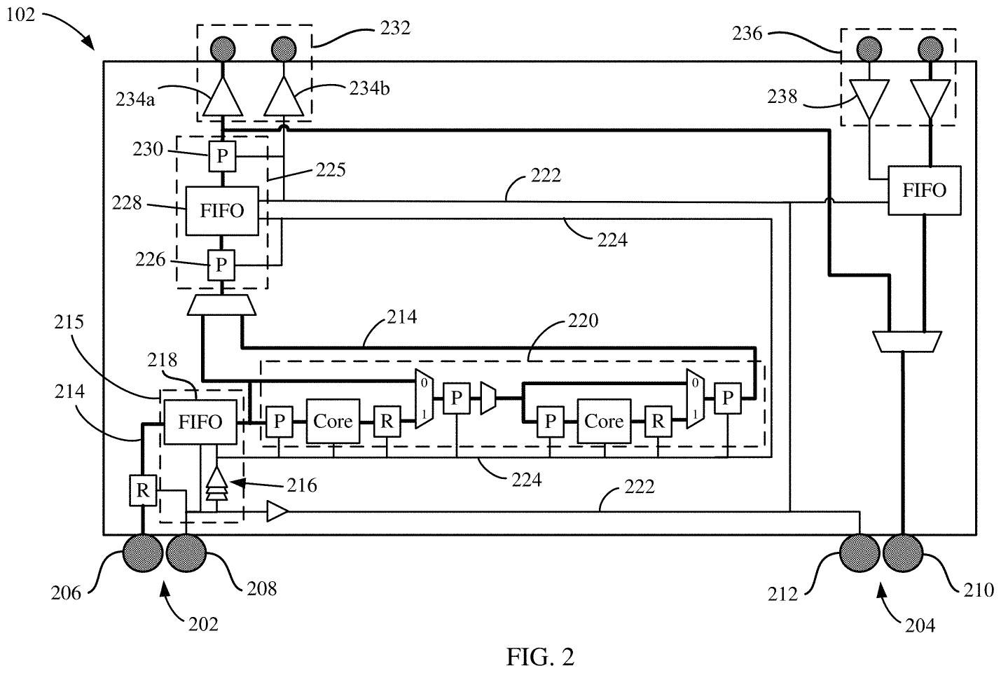

Referring to FIG. 2, a schematic diagram of the first die 102 is shown, depicting select components according to at least one aspect of the present disclosure. As shown, the first die 102 may include a test input interface 202 and a test output interface 204. The test input interface 202 may include one or more test data signal interconnects 206 and a test clock input interconnect 208. The test output interface 204 may include one or more test response signal interconnects 210 and a test clock output interconnect 212.

The first die 102 may further include a first test signal path 214. In at least one example, the first test signal path 214 may be configured to transition the test data signals from a source test clock (e.g., the source test clock received at the test clock input interconnect 208 of the test input interface 202) to a first balanced clock tree 224 having a higher latency compared to the source test clock. For example, the first die 102 may include a first transition circuit 215 configured to receive the test data signals from the test input interface 202, and to transition the test data signals from the source test clock to the first balanced clock tree 224 having a relatively higher latency. In the example depicted, the first transition circuit 215 includes a plurality of buffers 216 and a synchronous FIFO (first-in-first-out) 218 with clock inputs from both the source test clock and the first balanced clock tree 224. It will be apparent that various configurations of a transition circuit capable of transitioning the test data signals to a first balanced clock tree 224 may be utilized. In any such examples, the first balanced clock tree 224 will have a relatively higher latency compared to the source test clock. As used herein, a “transition” from one clock (e.g., the source test clock) to a different clock (e.g., the first balanced clock tree 224) refers to test data signals and/or test responses transitioning from circuitry employing the first clock signal to circuitry employing the second clock signal.

With the test data signals transitioned to the first balanced clock tree 224, the test data signals may be received along the first test signal path 214 by a first testing circuit 220. As shown, the first testing circuit 220 may include positive edge flops P, one or more cores, negative edge flops R, as well as multiplexors and other relevant components. It should be understood that the specific circuitry for the first testing circuit 220 will depend on the specific application and will vary according to such differing applications.

The first die 102 further includes a second transition circuit 225 configured to transition the test data signals from the first balanced clock tree 224 to a low-latency test clock signal on a first low-latency clock path 222. The first low-latency clock path 222 may be configured to convey the source test clock signal from the test clock input interconnect 208 along a low-latency clock path to the second die 104. The second transition circuit 225 may further transition the test responses from the first testing circuit 220 from the first balanced clock tree 224 to the low-latency test clock signal on the first low-latency clock path 222. In the depicted example, the second transition circuit 225 includes a positive edge flop 226 utilizing the first balanced clock tree 224, a FIFO 228 receiving clock inputs from both the first balanced clock tree 224 and the low-latency test clock signal from the first low-latency clock path 222, and a positive edge flop 230 utilizing the low-latency test clock signal. It should again be apparent that various configurations of a transition circuit capable of transitioning the test data signals and the test responses from the first balanced clock tree 224 to the low-latency clock signal may be utilized.

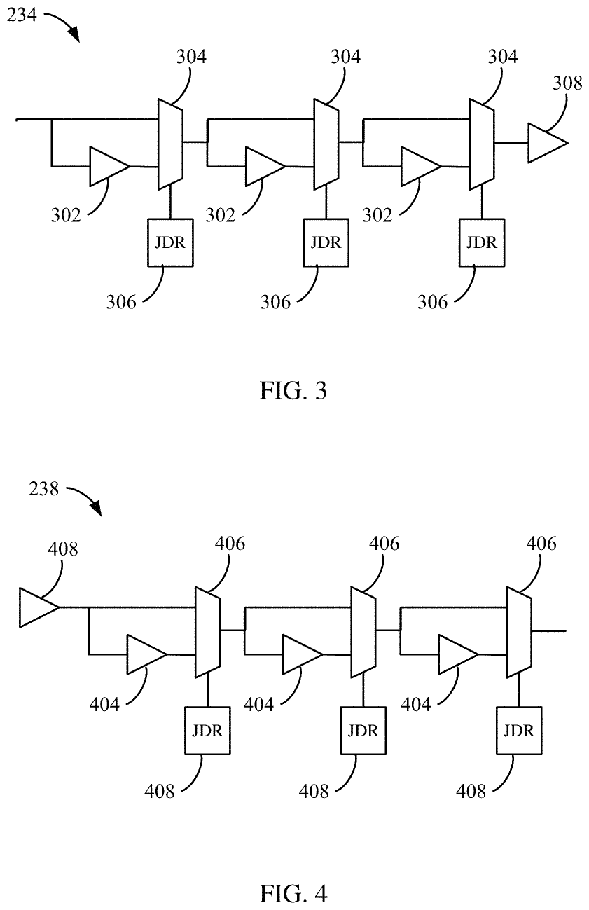

According to further aspects of the present disclosure, the first die 102 may include at least one first die-to-die output interface 232 configured to convey the test data signals and the low-latency clock received from the first low-latency clock path 222 to the second die 104. These test data signals may be similar to those received at the test data signal interconnects 206, or could be modified in the first die 102, according to different examples. The first die-to-die output interface 232 includes a plurality of output tunable delay circuits 234. For example, the plurality of output tunable delay circuits 234 may include at least one output tunable delay circuit 234a for the test data signals and an output tunable delay circuit 234b for the clock signal received from the first low-latency clock path 222. Each output tunable delay circuit 234a and 234b may be any suitable tunable delay circuit according to various aspects. FIG. 3 is a schematic diagram illustrating an output tunable delay circuit 234 according to at least one example. As shown, the output tunable delay circuit 234 may include a plurality of buffers 302, multiplexors 304, and JDRs (Jtag Data Registers) 306. Further, at the end of the depicted circuit, the output tunable delay circuit 234 includes a voltage level shifter (VLS) 308.

Referring again to FIG. 2, the first die 102 further includes at least one first die-to-die input interface 236 configured to receive test responses and a clock signal from the second die. The first die-to-die input interface 236 includes a plurality of input tunable delay circuits 238. For example, the input tunable delay circuitry 238 may include at least one input tunable delay circuit 238 for the received test responses and an input tunable delay circuit 238 for the clock signal received from the second die 104. The input tunable delay circuit 238 may be any suitable tunable delay circuit according to various embodiments. FIG. 4 is a schematic diagram illustrating an input tunable delay circuit 238 according to at least one example. As shown, the input tunable delay circuit 238 may include a VLS 402 leading to a plurality of buffers 404, multiplexors 406, and JDRs 408.

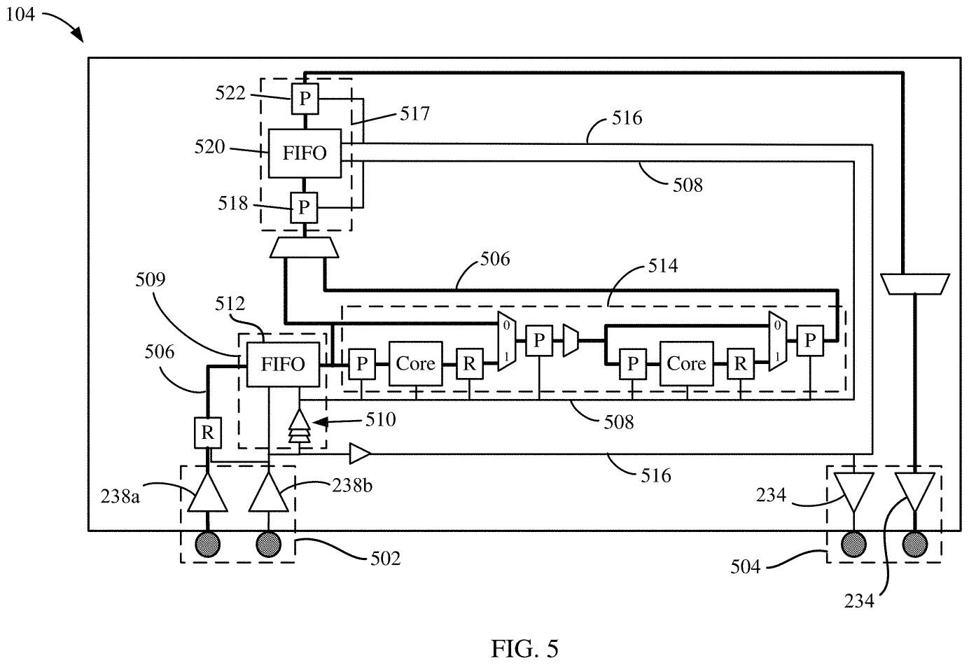

Turning to FIG. 5, a schematic diagram is shown of a second die 104 depicting select components according to at least one aspect. As shown, the second die 104 may include at least one second die-to-die input interface 502 coupled to the at least one die-to-die output interface 232 of the first die 102 in FIG. 2. The at least one second die-to-die input interface 502 may be configured to receive the test data signals and the low-latency clock signal from the first die 102. The second die-to-die input interface 502 includes a plurality of input tunable delay circuits 238. For example, the plurality of input tunable delay circuits 238 may include at least one input tunable delay circuit 238a for the test data signals and an input tunable delay circuit 238b for the low-latency clock signal received from the first die 102 along the first low-latency clock path 222 in in the first die 102 of FIG. 2. Each input tunable delay circuit 238a and 238b may be any suitable tunable delay circuit according to various embodiments, including the input tunable delay circuit 238 according to the example in FIG. 4.

The second die 104 further includes at least one second die-to-die output interface 504 configured to convey test responses and a clock signal to the first die 102. The second die-to-die output interface 504 includes a plurality of output tunable delay circuits 234. For example, the plurality of output tunable delay circuits 234 may include at least one output tunable delay circuit 234 for test responses generated at the second die 104 and an output tunable delay circuit 234 for the clock signal from the second die 104. The output tunable delay circuit 234 may be any suitable tunable delay circuit according to various embodiments, including the output tunable delay circuit 234 according to the example in FIG. 3.

The second die 104 also includes a second test signal path 506. In at least one aspect, the second test signal path 506 may be configured to transition the test data signals from the low-latency clock signal received at the second die-to-die input interface 502 to a second balanced clock tree 508 having a higher latency compared to the received low-latency clock signal. For example, the second die 104 may include a third transition circuit 509 configured to receive the test data signals from the second die-to-die input interface 502, and to transition the test data signals from the low-latency clock signal received from the second die-to-die input interface 502 to the second balanced clock tree 508. In the example depicted, the third transition circuit 509 includes a plurality of buffers 510 and a synchronous FIFO 512 with clock inputs from both the low-latency clock and the second balanced clock tree 508. It will be apparent that various configurations of a transition circuit capable of transitioning the test data signals to the second balanced clock tree 508 may be utilized. In any such embodiments, the second balanced clock tree 508 will have a relatively higher latency compared to the low-latency clock signal received from the second die-to-die input interface 502.

With the test data signals transitioned to the second balanced clock tree 508, the test data signals may be received along the second test signal path 506 by a second testing circuit 514. Like the first testing circuit 220 in the first die 102 in FIG. 2, the second testing circuit 514 may include positive edge flops P, one or more cores, negative edge flops R, as well as multiplexors and other relevant components. However, it should again be understood that the specific circuitry for the second testing circuit 514 will depend on the specific application and may vary according to such differing applications.

The second die 104 also includes a second low-latency clock path 516 configured to convey the low-latency clock signal from the second die-to-die input interface 502 to a fourth transition circuit 517. The fourth transition circuit 517 is configured to transition test data signals (if conveying to a third die, not shown) from the second balanced clock tree 508 to the low-latency clock signal on the second low-latency clock path 516. The fourth transition circuit 517 may further transition the test responses from the second testing circuit 514 from the second balanced clock tree 508 to the low latency clock signal on the second low-latency clock path 516. In the depicted example, the fourth transition circuit 517 includes a positive edge flop 518 utilizing the second balanced clock tree 508, a FIFO 520 receiving clock inputs from both the second balanced clock tree 508 and the low-latency clock signal on the second low-latency clock path 516, and a positive edge flop 522 utilizing the low-latency clock signal. It should again be apparent that various configurations of a transition circuit capable of transitioning test data signals and test responses from the second balanced clock tree 508 to the low-latency clock signal may be utilized.

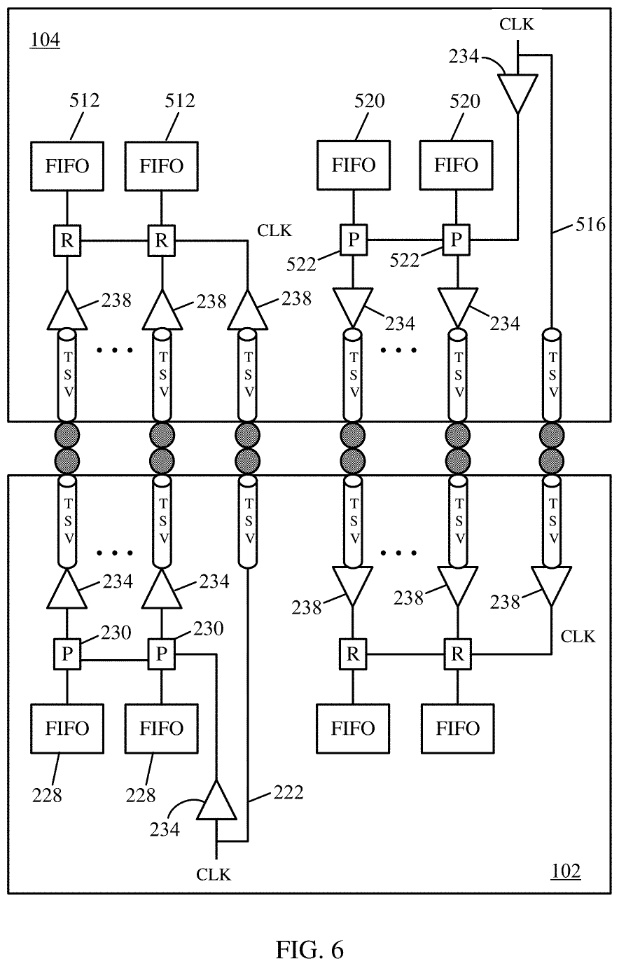

Although the examples in FIGS. 2 and 5 illustrate just a single bit interface for the test data signal, it should be understood that similar features can be employed for a bus interface architecture. For example, FIG. 6 is a schematic diagram illustrating an example bus interface architecture between the first die 102 and the second die 104 according to at least one embodiment. As shown in FIG. 6, several embodiments of the first die 102 and the second die 104 may include a bus interface, where each test data bit signal path includes a respective output tunable delay circuit 234 and respective input tunable delay circuit 238. More specifically, the first die 102 includes a respective synchronous FIFO 228, positive edge flop 230, and output tunable delay circuit 234 on each test data bit signal path prior to a respective through substrate via (TSV, or through silicon via) leading to respective interconnects. Similarly, the second die 104 includes a respective TSV, input tunable delay circuit 238, negative edge flop R, and synchronous FIFO 512.

On the return path, from the second die 104 to the first die 102, each test data bit signal path on the bus can include a respective synchronous FIFO 520, a respective positive edge flop 522, and a respective output tunable delay circuit 234. Following each respective output tunable delay circuit 234 on the second die 104, each test data bit signal is conveyed to the first die 102 including a respective TSV, input tunable delay circuit 238, negative edge flop R, and synchronous FIFO.

In FIG. 6, a portion of the first low-latency clock path 222 and second low-latency clock path 516 are also depicted to illustrate an example of conveying the low-latency clock signals from the first die 102 to the second die 104, and then from the second die 104 to the first die 102.

The tunable delay circuits for each test data bit signal path in the bus can help to maintain test data signal coherency when the test data signals are transferred from die to die. Additionally, these tunable delay circuits provide granular delay control on both clock and data transfers between dies. The tunable delay circuits provide clock path delay control for coarse delay tuning, and data path delay control for fine delay tuning per bit. Further, the tunable delay circuits enable the dies to be tuned on the fly.

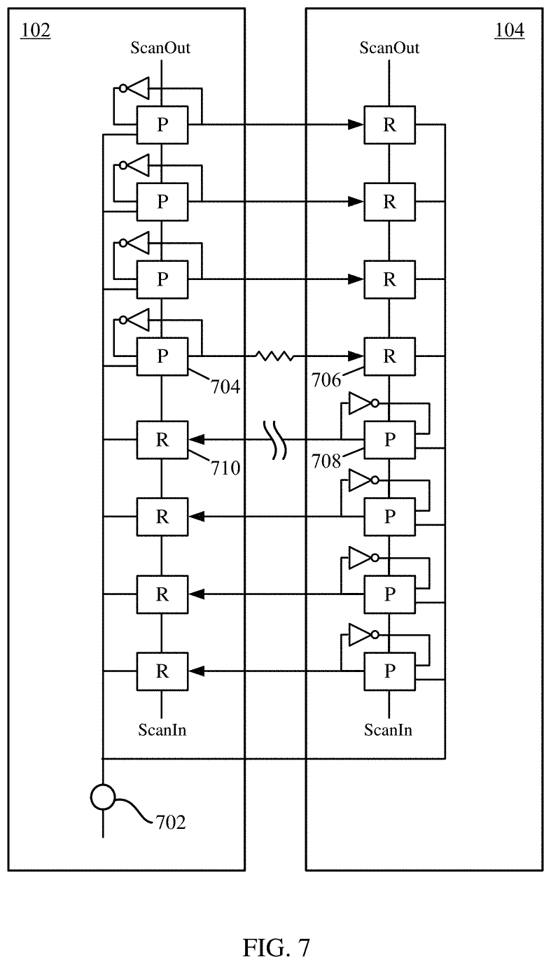

Additional features of the present disclosure include 3D stacked ICs including die-to-die interfaces configured to debug, diagnose, and repair the test data signal paths between dies. For instance, the first die-to-die output interface 232 and the second die-to-die input interface 502 may be configured to debug, diagnose, and repair the test data signal paths between the first die 102 and the second die 104. Similarly, the first die-to-die input interface 236 and the second die-to-die output interface 504 may be configured to debug, diagnose, and repair the test data signal paths between the first die 102 and the second die 104. For example, the last stage of the pipeline flops, such as the positive edge flop 230 in FIG. 6 can be stitched in a scan chain for each die. FIG. 7 is a schematic diagram illustrating an example of an architecture for facilitating interface debugging and diagnoses according to at least one embodiment. As shown, the positive edge flip flops P in the first die 102 of FIG. 7 may be positive edge flops 230 from FIG. 6, and the positive edge flip flops P in the second die 104 may be positive edge flops 522 in FIG. 6. Similarly, the negative edge flip flops R in FIG. 7 may be negative edge flops R in FIG. 6.

As shown, the positive edge flops P and negative edge flops R are stitched together in a scan chain for each of the first die 102 and the second die 104, along with an on-chip clock controller (OCC) 702 driving both the first die 102 and the second die 104. With the depicted embodiment, a test signal can be launched from one die and captured at the other die at each flop location. The test transitions can be launched at high speeds or low speeds, as desired. Based on the scan shift out data, an accurate determination can be made to identify which bits of scan data has data coherency issues.

As a specific example, a value can be conveyed from a first positive edge flop 704 of the first die 102 to be captured on a first negative edge flop 706 of the second die 104. In the depicted example, the value conveyed from the first positive edge flop 704 may be accurately captured by the first negative edge flop 706, but the capture is delayed from what it should be. When the test results are shifted out through the scan chain, a determination can be made that the connection between the first positive edge flop 704 of the first die 102 and the first negative edge flop 706 of the second die 104 is experiencing a delay defect. By knowing where the defect is occurring and that the defect is a delay defect, the first die 102 can employ the output tunable delay circuit 234 (shown in FIGS. 2, 3, & 6) and/or the second die 104 can employ the input tunable delay circuit 238 (shown in FIGS. 4, 5 & 6) to repair the delay defect at the specified location.

According to another example in the depicted embodiment, a value is also conveyed from a second positive edge flop 708 of the second die 104 to a second negative edge flop 710 of the first die 102. In this example, the value is not captured at the second negative edge flop 710 because of some defect inhibiting the value from being successfully conveyed from the second die 104 to the first die 102. The results will be shifted out through the scan chain, and a determination can be made that a static defect exists at the specific data path.

In some embodiments of the present disclosure, spare TSVs may be employed to facilitate repairing the static defect between the second positive edge flop 708 and the second negative edge flop 710. For example, referring to FIG. 11, a schematic diagram is depicted illustrating an example of a repairable interconnect between the first die and the second die according to at least one aspect. As shown one or more spare TSVs 1102 may be included between the first die 102 and the second die 104. To facilitate reparability, the TSVs may be configurable on each of the first die 102 and the second die 104. As a result, a selection to a redundant TSV may be made when a failure occurs in another TSV. In some examples, the selection of a spare TSV 1102 may be controlled by a configurable register, such as a plurality of JDRs, and fuses 1104. For example, one or more fuses 1104 may associated with each TSV 1102 to facilitate selection and/or deselection of each TSV. After TSV tests are completed, configurable register values can be blown on the fuses 1104. Although a specific example is provided in FIG. 11, it should be understood that other configurations for repair may also be employed according to different implementations. As a result of the foregoing, some examples of the present disclosure can identify defects, as well as repair those defects in the stacked circuit.

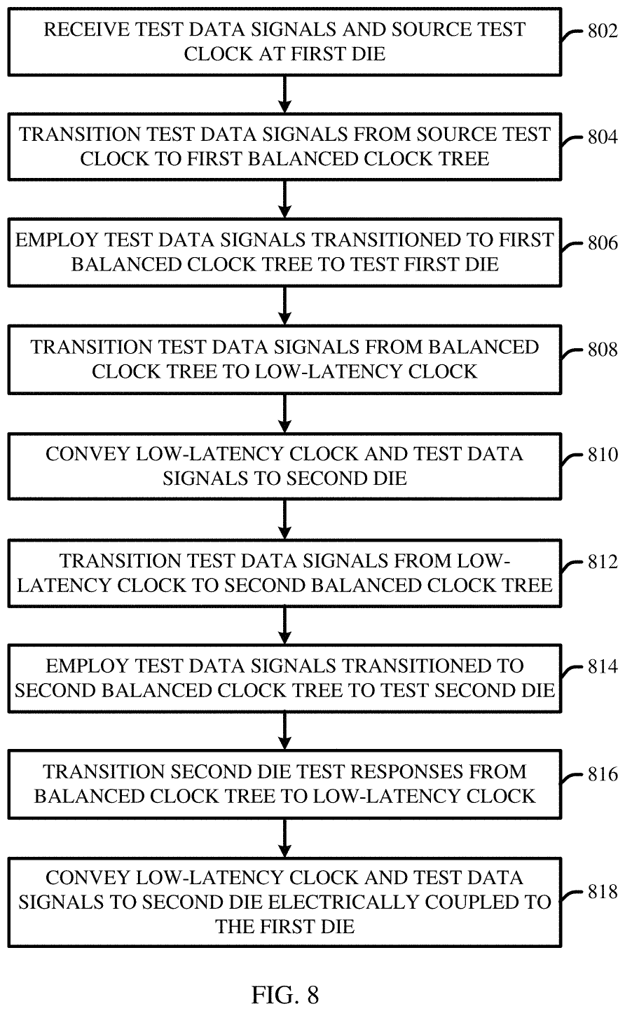

In operation, multiple stacked dies of a 3D stacked integrated circuit can be tested, and even repaired. FIG. 8 is a flow diagram illustrating at least one example of a method operational on a stacked circuit, such as the stacked circuit 100 including at least a first die 102 and at least a second die 104. With reference to FIGS. 2, 5, and 8, test data signals and a source test clock are received at the first die 102, at step 802. For example, the test data signals can be received in the test data signal interconnects 206 of the first die 102, and a source test clock signal can be received in the test clock input interconnect 208 of the first die 102.

At 804, the test data signals may be transitioned to a first balanced clock tree. For example, the test clock signal may be converted through a plurality of buffers 216 to generate the first balanced clock tree 224. Additionally, the test clock signal may be split along a first low-latency clock path 222, resulting in a first low-latency clock. The test data signals are conveyed along the first test signal path 214, where the test data signals are transitioned to the first balanced clock tree 224 in the first transition circuit 215. In the example in FIG. 2, the first transition circuit 215 may utilize the synchronous FIFO 218 to transition the test data signals to the first balanced clock tree 224.

At 806, the test data signals transitioned to the first balanced clock tree 224 may be employed to test the first die 102. For example, the first testing circuit 220 may utilize the test data signals transitioned to the first balanced clock tree 224 to test the first die 102.

At 808, the test data signals are then transitioned from the first balanced clock tree 224 to the low-latency clock signal conveyed along the first low-latency clock path 222. More specifically, the test data signals may be transitioned to the low-latency clock utilizing the positive edge flop 226, the synchronous FIFO 228, and the positive edge flop 230. Similarly, the resulting test responses from the first testing circuit 220 may also be transitioned from the first balanced clock tree 224 to the low-latency clock. The resulting first die test responses can be conveyed to the test response signal interconnects 210.

At 810, the low-latency clock, together with the test data signals converted to the low-latency clock are conveyed to the second die 104. For example, low-latency clock and the test data signals converted to the low-latency clock can be conveyed the first die-to-die output interface 232. At the first die-to-die output interface 232, the test data signals and the low-latency clock signal may be tuned in the respective output tunable delay circuits 234, and conveyed to the second die-to-die input interface 502 of the second die 104.

At the second die-to-die input interface 502 of the second die 104, the received test data signals and the low-latency clock signal are tuned in the input tunable delay circuit 238. The low-latency clock signal is converted to a second balanced clock tree 508 utilizing the plurality of buffers 510, and also maintained as a low-latency clock signal conveyed along the second low-latency clock path 516.

At 812, the test data signals may be transitioned from the low-latency clock to the second balanced clock tree 508. More specifically, the test data signals may be conveyed along the second test signal path 506, where the test data signals are transitioned to the second balanced clock tree 508 in the first transition circuit 215.

At 814, the test data signals transitioned to the second balanced clock tree 508 may be employed to test the second die 104. For example, the test data signals transitioned to the second balanced clock tree 508 may be utilized by the second testing circuit 514 to test the second die 104, resulting in second die test responses.

At 816, the second die test responses from the second testing circuit 514 may be transitioned from the second balanced clock tree 508 to the low-latency clock signal. For example, the second die test responses, and any test data signals that may be conveyed to a third die stacked on the second die 104, may be transitioned from the second balanced clock tree 508 to the low-latency clock signal conveyed along the second low-latency clock path 516 utilizing, for example, the positive edge flop 518, the synchronous FIFO 520, and the positive edge flop 522.

At 818, the resulting test responses, together with the low-latency clock signal, can be conveyed to the first die 102. For example, the resulting test responses and the low-latency clock signal can be conveyed to the second die-to-die output interface 504. At the second die-to-die output interface 504, the resulting test responses and the low-latency clock signal may be tuned in the output tunable delay circuit 234, and conveyed to the first die-to-die input interface 236 of the first die 102. At the first die-to-die input interface 236 of the first die 102, the resulting test responses received from the second die 104 and the low-latency clock signal may be tuned in the input tunable delay circuit 238. The resulting test responses received from the second die 104 and resulting test responses from the first die 102 can be conveyed to the test response signal interconnects 210 of the test output interface 204 of the first die 102.

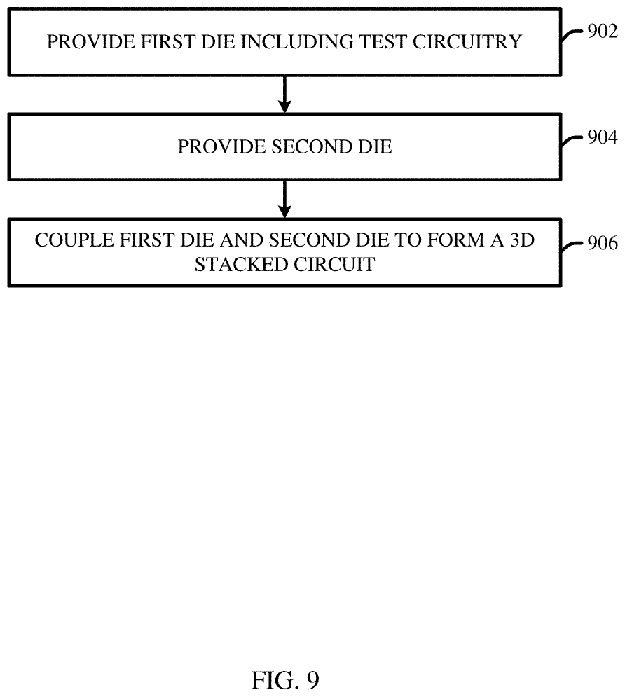

Additional aspects of the present disclosure include methods of making a stacked circuit, such as one or more examples of 3D stacked IC described herein. FIG. 9 is a flow diagram illustrating at least one example of a method of making a stacked circuit described herein. Referring to FIGS. 2, 6, and 9, a first die 102 may be provided at 902. The first die 102 may include a test input interface 202 configured to receive test data signals and a source test clock signal, and a test output interface 204 configured to convey test responses. The first die 102 may further include a first test signal path 214 configured to transition the test data signals from a source test clock to a first balanced clock tree 224, to test the first die 102 using the test data signals transitioned to the first balanced clock tree 224, to transition the test data signals and resulting test responses from the first balanced clock tree 224 to a low-latency clock, and to convey resulting test responses to the test output interface 204.

More specifically, the first test signal path 214 may include a first transition circuit 215, a first testing circuit 220, and a second transition circuit 225. The first transition circuit 215 is configured to receive the test data signals from the test input interface 202 and to transition the test data signals from the source test clock to the first balanced clock tree 224, where the first balanced clock tree 224 has a higher latency compared to the source test clock. The first testing circuit 220 is configured to receive the test data signals from the first transition circuit 215 and to test the first die 102 utilizing the test data signals. The second transition circuit 225 is configured to receive test data signals and resulting test responses from the first testing circuit 220 to transition the test data signals and resulting test responses from the first balanced clock tree 224 to the low-latency clock prior to conveying the resulting test responses to the test output interface 204 and the test data signals to the at least one first die-to-die output interface 232.

The provided first die 102 may further include the at least one first die-to-die output interface 232 configured to convey to the second die 104 the test data signals and a low-latency clock signal received from a first low-latency clock path 222 between the test input interface 202 and the at least one first die-to-die output interface 232, and at least one first die-to-die input interface 236 configured to receive test responses and the clock signal from the second die 104. According to various examples, the first die-to-die output interface 232 may include at least one output tunable delay circuit 234 for the test data signals, and an output tunable delay circuit for the low-latency clock signal. Similarly, the at least one first die-to-die input interface 236 may include at least one input tunable delay circuit 238 for the received test responses from the second die 104, and an input tunable delay circuit 238 for the low-latency clock signal received from the second die 104.

At 904, a second die 104 may be provided. The second die 104 may include at least one second die-to-die input interface 502, a second die-to-die output interface 504, and a second test signal path 506. The at least one second die-to-die input interface 502 may be electrically coupled to the at least one first die-to-die output interface 232 of the first die 102, and configured to receive the test data signals and the low-latency clock signal from the first die 102. The second die-to-die output interface 504 may be configured to convey test responses and the low-latency clock signal to the first die 102. The second test signal path 506 may be configured to transition the test data signals from the low-latency clock to a second balanced clock tree 508, to test the second die 104 using the test data signals transitioned to the second balanced clock tree 508, to transition the resulting test responses from the second balanced clock tree 508 back to the low-latency clock, and to convey resulting test responses to the second die-to-die output interface 504.

The second test signal path 506 may include a third transition circuit 509, a second testing circuit 514, and a fourth transition circuit 517. The third transition circuit 509 may be configured to receive the test data signals from the at least one second die-to-die input interface 502, and to transition the test data signals from the low-latency clock to the second balanced clock tree 508. The second testing circuit 514 may be configured to receive the test data signals from the third transition circuit 509 and to test the second die 104 utilizing the test data signals. The fourth transition circuit 517 may be configured to receive resulting test responses from the second testing circuit 514, and to transition the resulting test responses from the second balanced clock tree 508 to the low-latency clock prior to conveying the resulting test responses to the second die-to-die output interface 504.

According to various examples, the at least one second die-to-die input interface 502 may include at least one input tunable delay circuit 238 for the test data signals, and an input tunable delay circuit 238 for the low-latency clock signal. Similarly, the at least one second die-to-die output interface 504 may include at least one output tunable delay circuit 234 for the resulting test responses from the second die 104, and an output tunable delay circuit 234 for the low-latency clock signal.

In at least some implementations, the first die-to-die output interface 232 and the second die-to-die input interface 502 may be coupled together to form a stitched scan chain to test signal connections for each test data signal path from the first die-to-die output interface 232 to the second die-to-die input interface 502. Similarly, the first die-to-die input interface 236 and the second die-to-die output interface 504 may be coupled together to form a stitched scan chain to test signal connections for each test data signal path from the second die-to-die output interface 504 to the first die-to-die input interface 236.

At 906 in FIG. 9, the first die 102 may be coupled to the second die 104 to form a 3D stacked circuit. For example, the second die 104 may be positioned on top of the first die 102, and electrically coupled to the first die 102 with a plurality of interconnects. More specifically, a plurality of interconnects at the first die-to-die output interface 232 can be respectively coupled to a plurality of interconnects the second die-to-die input interface 502, and, a plurality of interconnects at the first die-to-die input interface 236 can be respectively coupled to a plurality of interconnects at the second die-to-die output interface 504 to form a 3D stacked IC.

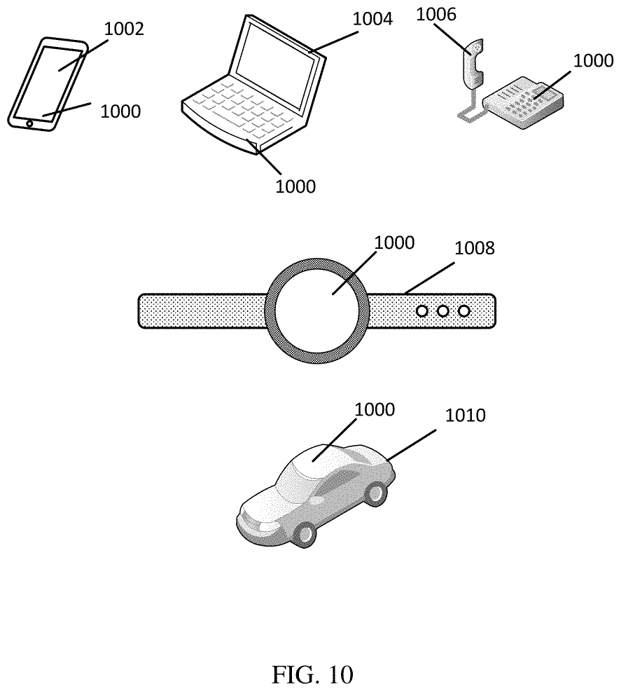

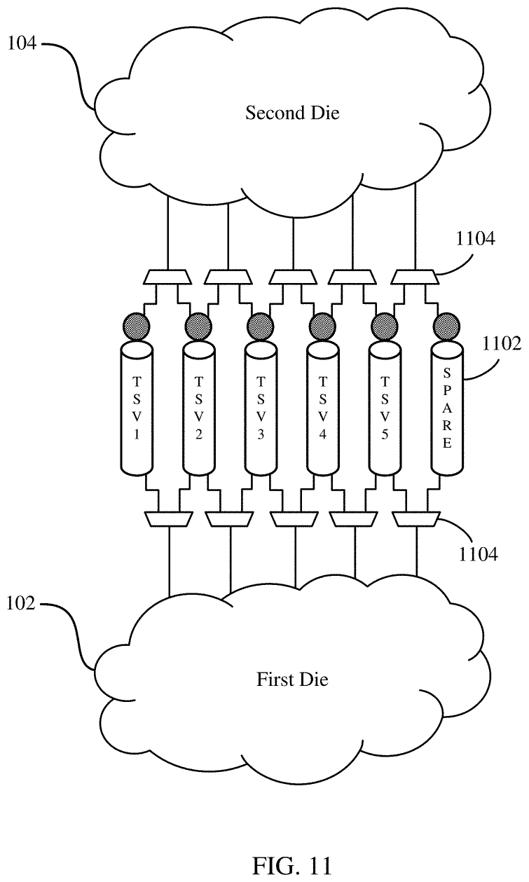

Various aspects of the disclosure may be incorporated into electronic devices. FIG. 10 illustrates various electronic devices that may be integrated with any of the aforementioned device, integrated device, 3D stacked integrated circuit (IC), 3D stacked integrated circuit (IC) device, semiconductor device, integrated circuit, die, interposer, package, package-on-package (PoP), System in Package (SiP), or System on Chip (SoC). For example, a mobile phone device 1002, a laptop computer device 1004, a fixed location terminal device 1006, a wearable device 1008, or automotive vehicle 1010 may include a device 1000 as described herein. The device 1000 may be, for example, any of the devices and/or integrated circuit (IC) packages described herein. The devices 1002, 1004, 1006 and 1008 and the vehicle 1010 illustrated in FIG. 10 are merely exemplary. Other electronic devices may also feature the device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

The various features described herein may include additional aspects, such as any single aspect or any combination of aspects described below and/or in connection with one or more other processes described elsewhere herein.

In a first aspect, a stacked circuit may include a first die electrically coupled to a second die through a plurality of interconnects, the first die including a test input interface configured to receive test data signals and a source test clock signal, a test output interface configured to convey test responses, a first test signal path configured to transition the test data signals from the source test clock to a first balanced clock tree, to test the first die using the test data signals transitioned to the first balanced clock tree, to transition the test data signals and resulting test responses from the first balanced clock tree to a low-latency clock, and to convey resulting test responses to the test output interface, at least one first die-to-die output interface configured to convey to the second die the test data signals and a low-latency clock signal received from a low-latency clock path between the test input interface and the at least one first die-to-die output interface, and at least one first die-to-die input interface configured to receive test responses and the clock signal from the second die.

In a second aspect, alone or in combination with the first aspect, the first test signal path may comprise a first transition circuit configured to receive the test data signals from the test input interface and to transition the test data signals from the source test clock to the first balanced clock tree, where the first balanced clock tree has a higher latency compared to the source test clock, a first testing circuit configured to receive the test data signals from the first transition circuit and to test the first die utilizing the test data signals, and a second transition circuit configured to receive test data signals and resulting test responses from the first testing circuit to transition the test data signals and resulting test responses from the first balanced clock tree to the low-latency clock prior to conveying the resulting test responses to the test output interface and the test data signals to the at least one first die-to-die output interface.

In a third aspect, alone or in combination with one or more of the first and second aspects, the at least one first die-to-die output interface may include at least one first tunable delay circuit for the test data signals and a first tunable delay circuit for the low-latency clock signal, and the at least one first die-to-die input interface may include at least one second tunable delay circuit for the received resulting test responses and a second tunable delay circuit for the received low-latency clock signal.

In a fourth aspect, alone or in combination with one or more of the first through third aspects, the stacked circuit may further include a plurality of TSVs and at least one spare TSV, and at least one respective fuse associated with each TSV to facilitate selection or deselection of each respective TSV.

In a fifth aspect, alone or in combination with one or more of the first through fourth aspects, the second die may include at least one second die-to-die input interface electrically coupled to the at least one first die-to-die output interface of the first die, the at least one second die-to-die input interface configured to receive the test data signals and the low-latency clock signal from the first die, a second die-to-die output interface configured to convey test responses and the low-latency clock signal to the first die, and a second test signal path configured to transition the test data signals from the low-latency clock to a second balanced clock tree, to test the second die using the test data signals transitioned to the second balanced clock tree, to transition the resulting test responses from the second balanced clock tree back to the low-latency clock, and to convey resulting test responses to the second die-to-die output interface.

In a sixth aspect, alone or in combination with one or more of the first through fifth aspects, the second test signal path may include a third transition circuit configured to receive the test data signals from the at least one second die-to-die input interface and to transition the test data signals from the low-latency clock to the second balanced clock tree, a second testing circuit configured to receive the test data signals from the third transition circuit and to test the second die utilizing the test data signals, and a fourth transition circuit configured to receive resulting test responses from the second testing circuit to transition the resulting test responses from the second balanced clock tree to the low-latency clock prior to conveying the resulting test responses to the second die-to-die output interface.

In a seventh aspect, alone or in combination with one or more of the first through sixth aspects, the at least one second die-to-die input interface may include at least one third tunable delay circuit for the received test data signals and a third tunable delay circuit for the received low-latency clock signal, and the at least one second die-to-die output interface may include at least one fourth tunable delay circuit for the resulting test responses from the second die, and a fourth tunable delay circuit for the low-latency clock signal.

In an eighth aspect, alone or in combination with one or more of the first through seventh aspects, the first die-to-die output interface and the second die-to-die input interface may include a stitched scan chain to test signal connections for each test data signal path from the first die-to-die output interface to the second die-to-die input interface.

In a ninth aspect, alone or in combination with one or more of the first through eighth aspects, the first die-to-die input interface and the second die-to-die output interface may include a stitched scan chain to test signal connections for each test data signal path from the second die-to-die output interface to the first die-to-die input interface.

In a tenth aspect, alone or in combination with one or more of the first through ninth aspects, the stacked circuit may be incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

In an eleventh aspect, an apparatus may include a first die electrically coupled to a second die in a 3D stacked circuit configuration, the first die configured to convey test data signals and a clock signal to the second die, wherein the first die includes a first tunable die-to-die output interface configured to tune at least one of the test data signals or the clock signal prior to being conveyed to the second die, and a first tunable die-to-die input interface configured to tune at least one of test response signals or the clock signal received from the second die, and the second die including a second tunable die-to-die input interface configured to tune the at least one of the test data signals or the clock signal received from the first die, and a second tunable die-to-die output interface configured to tune the at least one of the test response signals or the clock signal prior to being conveyed to the first die.

In a twelfth aspect, alone or in combination with the eleventh aspect, the first die may include a test input interface configured to receive the test data signals and a source test clock signal, a test output interface configured to convey test responses, a first test signal path configured to transition the test data signals from the source test clock to a first balanced clock tree, to test the first die using the test data signals transitioned to the first balanced clock tree, to transition the test data signals and resulting test responses from the first balanced clock tree to a low-latency clock, and to convey resulting test responses to the first tunable die-to-die output interface, and a low-latency clock path to convey the low-latency clock from the test input interface to the first tunable die-to-die output interface.

In a thirteenth aspect, alone or in combination with one or more of the eleventh or the twelfth aspects, the first test signal path may include a first transition circuit configured to receive the test data signals from the test input interface and to transition the test data signals from the source test clock to the first balanced clock tree, where the first balanced clock tree has a higher latency compared to the source test clock, a first testing circuit configured to receive the test data signals from the first transition circuit and to test the first die utilizing the test data signals, and a second transition circuit configured to receive test data signals from the testing circuit, and to transition the test data signals from the first balanced clock tree to the low-latency clock prior to conveying the test data signals to the first tunable die-to-die output interface.

In a fourteenth aspect, alone or in combination with one or more of the eleventh through thirteenth aspects, the second die may further include a second test signal path configured to transition the test data signals from the clock signal received from the first die to a second balanced clock tree, to test the second die using the test data signals transitioned to the second balanced clock tree, to transition resulting test responses from the second balanced clock tree to the received clock signal, and to convey resulting test responses to the second tunable die-to-die output interface.

In a fifteenth aspect, alone or in combination with one or more of the eleventh through fourteenth aspects, the second test signal path may include a third transition circuit configured to receive the test data signals from the second tunable die-to-die input interface and to transition the test data signals from a low-latency clock to the second balanced clock tree, a second testing circuit configured to receive the test data signals from the third transition circuit and to test the second die utilizing the test data signals, and a fourth transition circuit configured to receive resulting test responses from the second testing circuit, and to transition the resulting test responses from the second balanced clock tree to the low-latency clock prior to conveying the resulting test responses to the second tunable die-to-die output interface.

In a sixteenth aspect, alone or in combination with one or more of the eleventh through fifteenth aspects, the first tunable die-to-die output interface and the second tunable die-to-die input interface may include a stitched scan chain to test signal connections for each test data signal path from the first tunable die-to-die output interface to the second tunable die-to-die input interface, and the first tunable die-to-die input interface and the second tunable die-to-die output interface may include a stitched scan chain to test signal connections for each test data signal path from the second tunable die-to-die output interface to the first tunable die-to-die input interface.

In a seventeenth aspect, alone or in combination with one or more of the eleventh through sixteenth aspects, the apparatus may further include a plurality of TSVs and at least one spare TSV, and at least one respective fuse associated with each TSV to facilitate selection or deselection of each respective TSV.

In an eighteenth aspect, alone or in combination with one or more of the eleventh through seventeenth aspects, the apparatus may be selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

In a nineteenth aspect, a method for fabricating a stacked circuit may include providing a first die including a test input interface configured to receive test data signals and a source test clock signal, a test output interface configured to convey test responses, a first test signal path configured to transition the test data signals from the source test clock to a first balanced clock tree, to test the first die using the test data signals transitioned to the first balanced clock tree, to transition the test data signals and resulting test responses from the first balanced clock tree to a low-latency clock, and to convey resulting test responses to the test output interface, at least one first die-to-die output interface configured to convey to the second die the test data signals and a low-latency clock signal received from a low-latency clock path between the test input interface and the at least one first die-to-die output interface, and at least one first die-to-die input interface configured to receive test responses and the clock signal from the second die, providing the second die, and electrically coupling the first die and the second die together to form a 3D stacked circuit.

In a twentieth aspect, alone or in combination with the nineteenth aspect, providing the first die including the first test signal path may include providing the first die including a first test signal path comprising a first transition circuit configured to receive the test data signals from the test input interface and to transition the test data signals from the source test clock to the first balanced clock tree, where the first balanced clock tree has a higher latency compared to the source test clock, a first testing circuit configured to receive the test data signals from the first transition circuit and to test the first die utilizing the test data signals, and a second transition circuit configured to receive test data signals and resulting test responses from the first testing circuit to transition the test data signals and resulting test responses from the first balanced clock tree to the low-latency clock prior to conveying the resulting test responses to the test output interface and the test data signals to the at least one first die-to-die output interface.

In a twenty-first aspect, alone or in combination with one or more of the nineteenth or twentieth aspects, the at least one first die-to-die output interface may include at least one first tunable delay circuit for the test data signals, and a first tunable delay circuit for the low-latency clock signal, and the at least one first die-to-die input interface may include at least one second tunable delay circuit for the received resulting test responses, and a second tunable delay circuit for the received low-latency clock signal.

In a twenty-second aspect, alone or in combination with one or more of the nineteenth through twenty-first aspects, providing the second die may include providing the second die comprising at least one second die-to-die input interface electrically coupled to the at least one first die-to-die output interface of the first die, the at least one second die-to-die input interface configured to receive the test data signals and the low-latency clock signal from the first die, a second die-to-die output interface configured to convey test responses and the low-latency clock signal to the first die, and a second test signal path configured to transition the test data signals from the low-latency clock to a second balanced clock tree, to test the second die using the test data signals transitioned to the second balanced clock tree, to transition the resulting test responses from the second balanced clock tree back to the low-latency clock, and to convey resulting test responses to the second die-to-die output interface.

In a twenty-third aspect, alone or in combination with one or more of the nineteenth through twenty-second aspects, the second test signal path may include a third transition circuit configured to receive the test data signals from the at least one second die-to-die input interface and to transition the test data signals from the low-latency clock to the second balanced clock tree, a second testing circuit configured to receive the test data signals from the third transition circuit and to test the second die utilizing the test data signals, and a fourth transition circuit configured to receive resulting test responses from the second testing circuit to transition the resulting test responses from the second balanced clock tree to the low-latency clock prior to conveying the resulting test responses to the second die-to-die output interface.

In a twenty-fourth aspect, alone or in combination with one or more of the nineteenth through twenty-third aspects, the at least one second die-to-die input interface may include at least one third tunable delay circuit for the received test data signals, and a third tunable delay circuit for the received low-latency clock signal, and the at least one second die-to-die output interface may include at least one fourth tunable delay circuit for the resulting test responses from the second die, and a fourth tunable delay circuit for the low-latency clock signal.

In a twenty-fifth aspect, alone or in combination with one or more of the nineteenth through twenty-fourth aspects, the first die-to-die output interface and the second die-to-die input interface may include a stitched scan chain to test signal connections for each test data signal path from the first die-to-die output interface to the second die-to-die input interface, and the first die-to-die input interface and the second die-to-die output interface may include a stitched scan chain to test signal connections for each test data signal path from the second die-to-die output interface to the first die-to-die input interface.

In a twenty-sixth aspect, a method operational on a stacked circuit may include receiving test data signals and a source test clock in a first die, transitioning the test data signals from the source test clock to a first balanced clock tree, employing the test data signals transitioned to the first balanced clock tree to test the first die, wherein the test of the first die results in first die test responses, transitioning the test data signals to a low-latency clock, conveying the low-latency clock and the test data signals transitioned to the low-latency clock to a second die stacked on the first die and electrically coupled to the first die, transitioning the test data signals in the second die from the test clock to a second balanced clock tree, employing the test data signals transitioned to the second balanced clock tree to test the second die, wherein the test of the second die results in second die test responses, transitioning the second die test responses to the low-latency clock, and conveying the second die test responses and low-latency clock from the second die to the first die.

In a twenty-seventh aspect, alone or in combination with the twenty-sixth aspect, the method may further include tuning at least one of the low-latency clock or the test data signals when conveying the low-latency clock and test data signals to the second die, and tuning at least one of the low-latency clock or the second die test responses when conveying the low-latency clock and the second die test responses to the first die.

In a twenty-eighth aspect, alone or in combination with one or more of the twenty-sixth or twenty-seventh aspects, the method may further include conveying transition values from the first die to the second die along at least one test data signal path, shifting the results of the transition values through a scan chain, and detecting a connection defect along the at least one test data signal path based on the results on the scan chain.

In a twenty-ninth aspect, alone or in combination with one or more of the twenty-sixth through twenty-eighth aspects, conveying the test data signals transitioned to the low-latency clock to the second die may include conveying the test data signals transitioned to the low-latency clock to the second die on a plurality of test data signal paths forming a data bus.

In a thirtieth aspect, alone or in combination with one or more of the twenty-sixth through twenty-ninth aspects, conveying the second die test responses to the first die may include conveying the second die test responses to the first die on a plurality of test data signal paths forming a data bus.

One or more of the components, processes, features, and/or functions illustrated in FIGS. 1-10 may be rearranged and/or combined into a single component, process, feature or function or embodied in several components, processes, or functions. Additional elements, components, processes, and/or functions may also be added without departing from the disclosure. It should also be noted FIGS. 1-10 and its corresponding description in the present disclosure is not limited to dies and/or ICs. In some implementations, FIGS. 1-10 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The term “encapsulating” means that the object may partially encapsulate or completely encapsulate another object. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a redistribution metal layer, and/or an under bump metallization (UBM) layer. An interconnect may include one or more metal components (e.g., seed layer+metal layer). In some implementations, an interconnect is an electrically conductive material that may be configured to provide an electrical path for a current (e.g., a data signal, ground or power). An interconnect may be part of a circuit. An interconnect may include more than one element or component. An interconnect may be defined by one or more interconnects. Different implementations may use similar or different processes to form the interconnects. In some implementations, a chemical vapor deposition (CVD) process and/or a physical vapor deposition (PVD) process for forming the interconnects. For example, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features associate with the examples described herein and shown in the accompanying drawings can be implemented in different examples and implementations without departing from the scope of the present disclosure. Therefore, although certain specific constructions and arrangements have been described and shown in the accompanying drawings, such embodiments are merely illustrative and not restrictive of the scope of the disclosure, since various other additions and modifications to, and deletions from, the described embodiments will be apparent to one of ordinary skill in the art. Thus, the scope of the disclosure is only determined by the literal language, and legal equivalents, of the claims which follow.

1. A stacked circuit, comprising:
a first die electrically coupled to a second die through a plurality of interconnects, the first die including:
a test input interface configured to receive test data signals and a source test clock signal;
a test output interface configured to convey test responses;
a first test signal path configured to transition the test data signals from the source test clock to a first balanced clock tree, to test the first die using the test data signals transitioned to the first balanced clock tree, to transition the test data signals and resulting test responses from the first balanced clock tree to a low-latency clock, and to convey resulting test responses to the test output interface;
at least one first die-to-die output interface configured to convey to the second die the test data signals and a low-latency clock signal received from a low-latency clock path between the test input interface and the at least one first die-to-die output interface; and
at least one first die-to-die input interface configured to receive test responses and the clock signal from the second die.

2. The stacked circuit of claim 1, wherein the first test signal path comprises:
a first transition circuit configured to receive the test data signals from the test input interface and to transition the test data signals from the source test clock to the first balanced clock tree, where the first balanced clock tree has a higher latency compared to the source test clock;
a first testing circuit configured to receive the test data signals from the first transition circuit and to test the first die utilizing the test data signals; and
a second transition circuit configured to receive test data signals and resulting test responses from the first testing circuit to transition the test data signals and resulting test responses from the first balanced clock tree to the low-latency clock prior to conveying the resulting test responses to the test output interface and the test data signals to the at least one first die-to-die output interface.

3. The stacked circuit of claim 1, wherein:
the at least one first die-to-die output interface comprises at least one first tunable delay circuit for the test data signals, and a first tunable delay circuit for the low-latency clock signal; and
the at least one first die-to-die input interface comprises at least one second tunable delay circuit for the received resulting test responses, and a second tunable delay circuit for the received low-latency clock signal.

4. The stacked circuit of claim 1, further comprising:
a plurality of through substrate vias (TSVs) and at least one spare TSV; and
at least one respective fuse associated with each TSV to facilitate selection or deselection of each respective TSV.

5. The stacked circuit of claim 1, wherein the second die comprises:
at least one second die-to-die input interface electrically coupled to the at least one first die-to-die output interface of the first die, the at least one second die-to-die input interface configured to receive the test data signals and the low-latency clock signal from the first die;
at least one second die-to-die output interface configured to convey test responses and the low-latency clock signal to the first die; and
a second test signal path configured to transition the test data signals from the low-latency clock to a second balanced clock tree, to test the second die using the test data signals transitioned to the second balanced clock tree, to transition the resulting test responses from the second balanced clock tree back to the low-latency clock, and to convey resulting test responses to the second die-to-die output interface.

6. The stacked circuit of claim 5, wherein the second test signal path comprises:
a third transition circuit configured to receive the test data signals from the at least one second die-to-die input interface and to transition the test data signals from the low-latency clock to the second balanced clock tree;
a second testing circuit configured to receive the test data signals from the third transition circuit and to test the second die utilizing the test data signals; and
a fourth transition circuit configured to receive resulting test responses from the second testing circuit to transition the resulting test responses from the second balanced clock tree to the low-latency clock prior to conveying the resulting test responses to the second die-to-die output interface.

7. The stacked circuit of claim 5, wherein:
the at least one second die-to-die input interface comprises at least one third tunable delay circuit for the received test data signals, and a third tunable delay circuit for the received low-latency clock signal; and
the at least one second die-to-die output interface comprises at least one fourth tunable delay circuit for the resulting test responses from the second die, and a fourth tunable delay circuit for the low-latency clock signal.

8. The stacked circuit of claim 5, wherein the at least one first die-to-die output interface and the at least one second die-to-die input interface comprise a stitched scan chain to test signal connections for each test data signal path from the at least one first die-to-die output interface to the at least one second die-to-die input interface.

9. The stacked circuit of claim 8, wherein the at least one first die-to-die input interface and the at least one second die-to-die output interface comprise a stitched scan chain to test signal connections for each test data signal path from the at least one second die-to-die output interface to the at least one first die-to-die input interface.

10. The stacked circuit of claim 1, wherein the stacked circuit is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

11. An apparatus comprising:
a first die electrically coupled to a second die in a 3D stacked circuit configuration, the first die configured to convey test data signals and a clock signal to the second die, wherein the first die includes a first tunable die-to-die output interface configured to tune at least one of the test data signals or the clock signal prior to being conveyed to the second die, and a first tunable die-to-die input interface configured to tune at least one of test response signals or the clock signal received from the second die; and
the second die including a second tunable die-to-die input interface configured to tune the at least one of the test data signals or the clock signal received from the first die, and a second tunable die-to-die output interface configured to tune the at least one of the test response signals or the clock signal prior to being conveyed to the first die.

12. The apparatus of claim 11, the first die further comprising:
a test input interface configured to receive the test data signals and a source test clock signal;
a test output interface configured to convey test responses;
a first test signal path configured to transition the test data signals from the source test clock to a first balanced clock tree, to test the first die using the test data signals transitioned to the first balanced clock tree, to transition the test data signals and resulting test responses from the first balanced clock tree to a low-latency clock, and to convey resulting test responses to the first tunable die-to-die output interface; and
a low-latency clock path to convey the low-latency clock from the test input interface to the first tunable die-to-die output interface.

13. The apparatus of claim 12, wherein the first test signal path comprises:
a first transition circuit configured to receive the test data signals from the test input interface and to transition the test data signals from the source test clock to the first balanced clock tree, where the first balanced clock tree has a higher latency compared to the source test clock;
a first testing circuit configured to receive the test data signals from the first transition circuit and to test the first die utilizing the test data signals; and
a second transition circuit configured to receive test data signals from the testing circuit, and to transition the test data signals from the first balanced clock tree to the low-latency clock prior to conveying the test data signals to the first tunable die-to-die output interface.

14. The apparatus of claim 11, the second die further comprising:
a second test signal path configured to transition the test data signals from the clock signal received from the first die to a second balanced clock tree, to test the second die using the test data signals transitioned to the second balanced clock tree, to transition resulting test responses from the second balanced clock tree to the received clock signal, and to convey resulting test responses to the second tunable die-to-die output interface.

15. The apparatus of claim 14, wherein the second test signal path comprises:
a third transition circuit configured to receive the test data signals from the second tunable die-to-die input interface and to transition the test data signals from a low-latency clock to the second balanced clock tree;
a second testing circuit configured to receive the test data signals from the third transition circuit and to test the second die utilizing the test data signals; and
a fourth transition circuit configured to receive resulting test responses from the second testing circuit, and to transition the resulting test responses from the second balanced clock tree to the low-latency clock prior to conveying the resulting test responses to the second tunable die-to-die output interface.

16. The apparatus of claim 11, wherein:
the first tunable die-to-die output interface and the second tunable die-to-die input interface comprise a stitched scan chain to test signal connections for each test data signal path from the first tunable die-to-die output interface to the second tunable die-to-die input interface; and
the first tunable die-to-die input interface and the second tunable die-to-die output interface comprise a stitched scan chain to test signal connections for each test data signal path from the second tunable die-to-die output interface to the first tunable die-to-die input interface.

17. The apparatus of claim 11, further comprising:
a plurality of through substrate vias (TSVs) and at least one spare TSV; and
at least one respective fuse associated with each TSV to facilitate selection or deselection of each respective TSV.

18. The apparatus of claim 11, wherein the apparatus is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

19. A method for fabricating a stacked circuit, comprising:
providing a first die including:
a test input interface configured to receive test data signals and a source test clock signal;
a test output interface configured to convey test responses;
a first test signal path configured to transition the test data signals from the source test clock to a first balanced clock tree, to test the first die using the test data signals transitioned to the first balanced clock tree, to transition the test data signals and resulting test responses from the first balanced clock tree to a low-latency clock, and to convey resulting test responses to the test output interface;
at least one first die-to-die output interface configured to convey to a second die the test data signals and a low-latency clock signal received from a low-latency clock path between the test input interface and the at least one first die-to-die output interface; and
at least one first die-to-die input interface configured to receive test responses and the clock signal from the second die;
providing the second die; and
electrically coupling the first die and the second die together to form a 3D stacked circuit.

20. The method of claim 19, wherein providing the first die including the first test signal path comprises providing the first die including the first test signal path comprising:
a first transition circuit configured to receive the test data signals from the test input interface and to transition the test data signals from the source test clock to the first balanced clock tree, where the first balanced clock tree has a higher latency compared to the source test clock;
a first testing circuit configured to receive the test data signals from the first transition circuit and to test the first die utilizing the test data signals; and
a second transition circuit configured to receive test data signals and resulting test responses from the first testing circuit to transition the test data signals and resulting test responses from the first balanced clock tree to the low-latency clock prior to conveying the resulting test responses to the test output interface and the test data signals to the at least one first die-to-die output interface.

21. The method of claim 19, wherein:
the at least one first die-to-die output interface comprises at least one first tunable delay circuit for the test data signals, and a first tunable delay circuit for the low-latency clock signal; and
the at least one first die-to-die input interface comprises at least one second tunable delay circuit for the received resulting test responses, and a second tunable delay circuit for the received low-latency clock signal.

22. The method of claim 19, wherein providing the second die includes providing the second die comprising:
at least one second die-to-die input interface electrically coupled to the at least one first die-to-die output interface of the first die, the at least one second die-to-die input interface configured to receive the test data signals and the low-latency clock signal from the first die;
at least one second die-to-die output interface configured to convey test responses and the low-latency clock signal to the first die; and
a second test signal path configured to transition the test data signals from the low-latency clock to a second balanced clock tree, to test the second die using the test data signals transitioned to the second balanced clock tree, to transition the resulting test responses from the second balanced clock tree back to the low-latency clock, and to convey resulting test responses to the second die-to-die output interface.

23. The method of claim 22, wherein the second test signal path comprises:
a third transition circuit configured to receive the test data signals from the at least one second die-to-die input interface and to transition the test data signals from the low-latency clock to the second balanced clock tree;
a second testing circuit configured to receive the test data signals from the third transition circuit and to test the second die utilizing the test data signals; and
a fourth transition circuit configured to receive resulting test responses from the second testing circuit to transition the resulting test responses from the second balanced clock tree to the low-latency clock prior to conveying the resulting test responses to the second die-to-die output interface.

24. The method of claim 22, wherein:
the at least one second die-to-die input interface comprises at least one third tunable delay circuit for the received test data signals, and a third tunable delay circuit for the received low-latency clock signal; and
the at least one second die-to-die output interface comprises at least one fourth tunable delay circuit for the resulting test responses from the second die, and a fourth tunable delay circuit for the low-latency clock signal.

25. The method of claim 22, wherein:
the at least one first die-to-die output interface and the at least one second die-to-die input interface comprise a stitched scan chain to test signal connections for each test data signal path from the at least one first die-to-die output interface to the at least one second die-to-die input interface; and
the at least one first die-to-die input interface and the at least one second die-to-die output interface comprise a stitched scan chain to test signal connections for each test data signal path from the at least one second die-to-die output interface to the at least one first die-to-die input interface.

26. A method operational on a stacked circuit, comprising:
receiving test data signals and a source test clock in a first die;
transitioning the test data signals from the source test clock to a first balanced clock tree;
employing the test data signals transitioned to the first balanced clock tree to test the first die, wherein the test of the first die results in first die test responses;
transitioning the test data signals to a low-latency clock;
conveying the low-latency clock and the test data signals transitioned to the low-latency clock to a second die stacked on the first die and electrically coupled to the first die;
transitioning the test data signals in the second die from the test clock to a second balanced clock tree;
employing the test data signals transitioned to the second balanced clock tree to test the second die, wherein the test of the second die results in second die test responses;
transitioning the second die test responses to the low-latency clock; and
conveying the second die test responses and low-latency clock from the second die to the first die.

27. The method of claim 26, further comprising:
tuning at least one of the low-latency clock or the test data signals when conveying the low-latency clock and test data signals to the second die; and
tuning at least one of the low-latency clock or the second die test responses when conveying the low-latency clock and the second die test responses to the first die.

28. The method of claim 26, further comprising:
conveying transition values from the first die to the second die along at least one test data signal path;
shifting results of the transition values through a scan chain; and
detecting a connection defect along the at least one test data signal path based on the results on the scan chain.

29. The method of claim 26, wherein conveying the test data signals transitioned to the low-latency clock to the second die comprises:
conveying the test data signals transitioned to the low-latency clock to the second die on a plurality of test data signal paths forming a data bus.

30. The method of claim 26, wherein conveying the second die test responses to the first die comprises:
conveying the second die test responses to the first die on a plurality of test data signal paths forming a data bus.
